(19) United States
(12) Patent Application Publication
(10) Pub. No.: US 2012/0168848 A1
(43) Pub. Date: Jul. 5, 2012

(54) NON-VOLATILE MEMORY DEVICE AND METHOD FOR FABRICATING THE SAME

(75) Inventor: Jung-Ryul AHN, Icheon-si (KR)

(73) Assignee: HYNIX SEMICONDUCTOR INC., Icheon-si (KR)

(21) Appl. No.: 13/243,838

(22) Filed: Sep. 23, 2011

(30) Foreign Application Priority Data
Dec. 30, 2010 (KR) 10-2010-0138858

(51) Int. Cl. H01L 29/792; H01L 21/336

(52) U.S. Cl. 257/324; 438/591; 257/E29.309; 257/E21.423

(57) ABSTRACT

A non-volatile memory device includes a channel structure extended in a first direction that includes a plurality of inter-layer dielectric layers and a plurality of channel layers alternately stacked over a substrate such that each inter-layer dielectric layer is adjacent to a corresponding one of the plurality of channel layers. A word line extends in a second direction crossing the first direction over the channel structure, and a gate electrode protrudes from the word line in a downward direction to contact a sidewall of the channel structure. A memory gate insulation layer is interposed between the gate electrode and the channel structure, where sidewalls of the channel layers contacting the gate electrode are protruded toward the gate electrode, compared with sidewalls of the inter-layer dielectric layers.

### CROSS-REFERENCE TO RELATED APPLICATIONS

The present application claims priority of Korean Patent Application No. 10-2010-0138858, filed on Dec. 30, 2010, which is incorporated herein by reference in its entirety.

### BACKGROUND

1. Field

Exemplary embodiments of the present invention relate to a non-volatile memory device and a fabrication method thereof, and more particularly, to a non-volatile memory device including a plurality of memory cells stacked perpendicularly to a substrate, and a method for fabricating the same.

2. Description of the Related Art

Non-volatile memory devices retain stored data even when a power source is cut off. Diverse non-volatile memory devices, such as flash memory device, are widely used.

As the integration degree of a memory device fabricated as a two-dimensional memory device in a single layer over a silicon substrate reaches technical limitations, a three-dimensional non-volatile memory device in which a plurality of memory cells are stacked perpendicularly to a silicon substrate is proposed.

### SUMMARY

An embodiment of the present invention is directed to a non-volatile memory device that has an increased integration degree as a plurality of memory cells are stacked in a vertical direction, has an easy fabrication process, and stably performs a memory cell operation, and a method for fabricating the same.

In accordance with an embodiment of the present invention, a non-volatile memory device includes a channel structure, extended in a first direction, that includes a plurality of inter-layer dielectric layers and a plurality of channel layers alternately stacked over a substrate such that each inter-layer dielectric layer is adjacent to a corresponding one of the plurality of channel layers. The non-volatile memory device includes a word line over the channel structure that extends in a second direction crossing the first direction over the channel structure and a gate electrode that protrudes from the word line in a downward direction and contacts a sidewall of the channel structure. A memory gate insulation layer is interposed between the gate electrode and the channel structure, wherein sidewalls of the channel layers contacting the gate electrode are protruded toward the gate electrode, compared with sidewalls of the inter-layer dielectric layers.

In accordance with another embodiment of the present invention, a method for fabricating a non-volatile memory device includes forming a channel structure extended in a first direction and comprising a plurality of inter-layer dielectric layers and a plurality of channel layers alternately stacked over a substrate such that each inter-layer dielectric layer is adjacent to a corresponding one of the plurality of channel layers. The method may also comprise forming a memory gate insulation layer over a substrate structure including the channel structure, and forming a word line over the channel structure extended in a second direction crossing the first direction and a gate electrode that protrudes from the word line in a downward direction and contacting a sidewall of the channel structure over the memory gate insulation layer. The sidewalls of the channel layers contacting the gate electrode may protrude toward the gate electrode compared with sidewalls of the inter-layer dielectric layers.

### BRIEF DESCRIPTION OF THE DRAWINGS

FIGS. 1A to 1G illustrate a non-volatile memory device having a three-dimensional structure in accordance with an embodiment of the present invention.

FIGS. 2A to 4E illustrate a method for fabricating a non-volatile memory device having a three-dimensional structure in accordance with an embodiment of the present invention.

FIGS. 5A to 6E illustrate a non-volatile memory device having a three-dimensional structure and a method for fabricating the non-volatile memory device in accordance with another embodiment of the present invention.

### DETAILED DESCRIPTION

Exemplary embodiments of the present invention will be described below in more detail with reference to the accompanying drawings. The present invention may, however, be embodied in different forms and should not be construed as being limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where at least a third layer exists between the first layer and the second layer or the substrate.

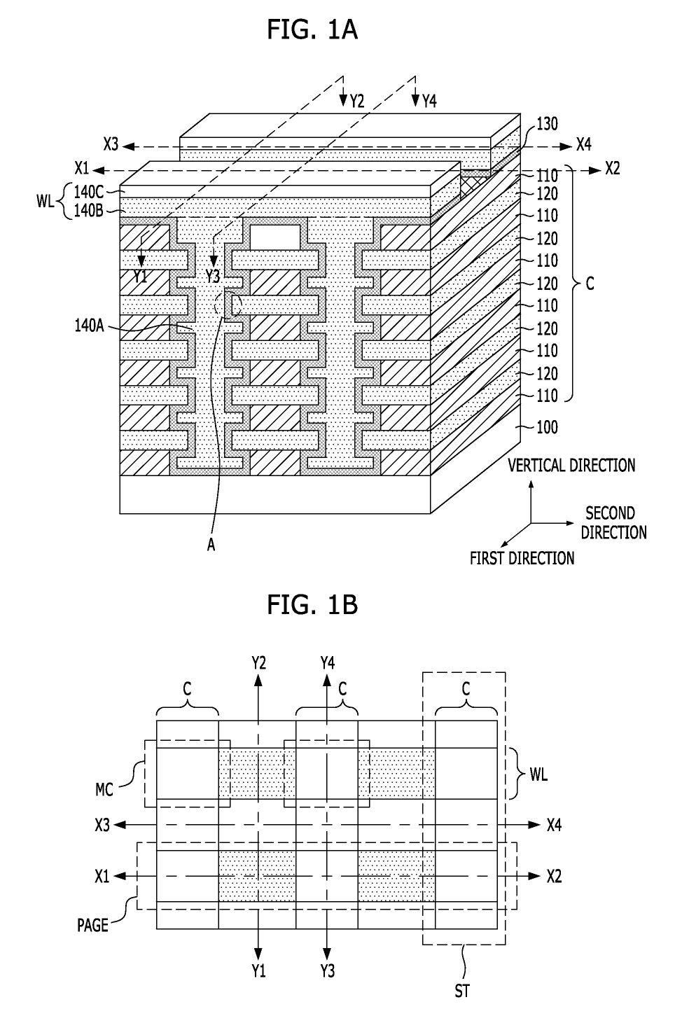

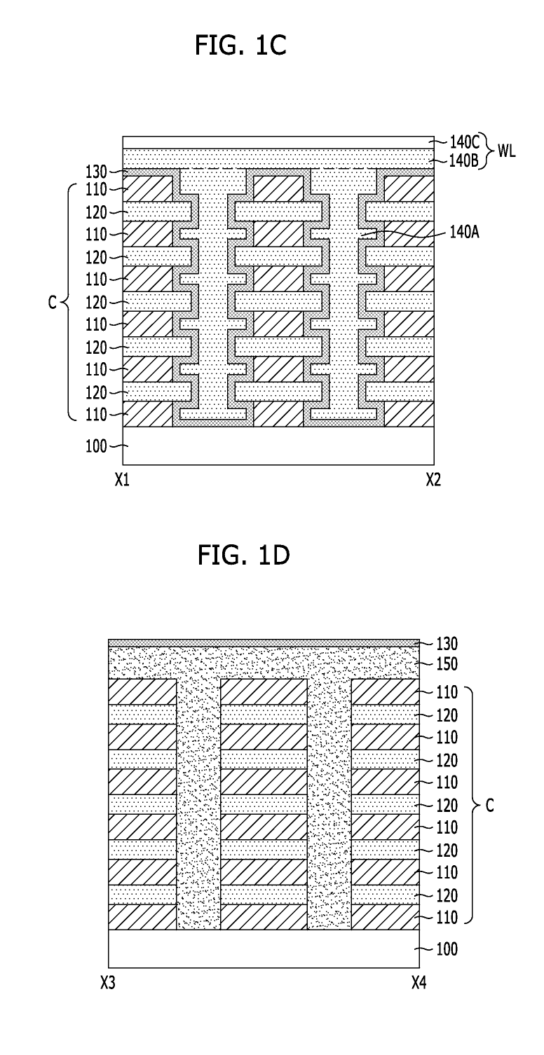

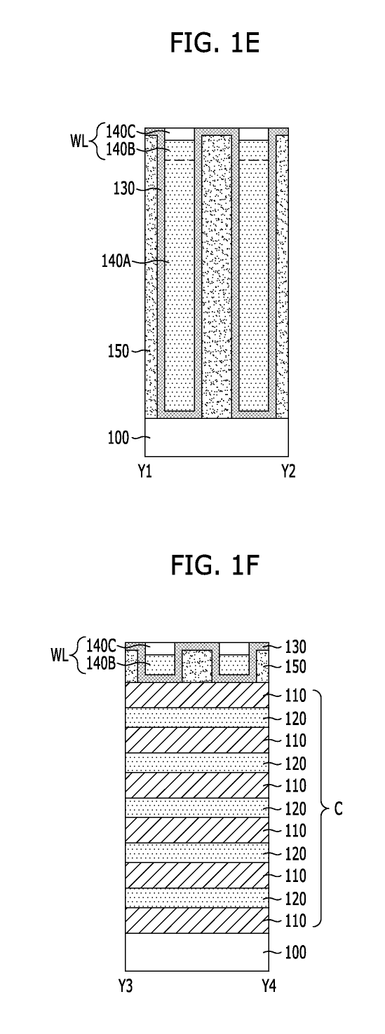

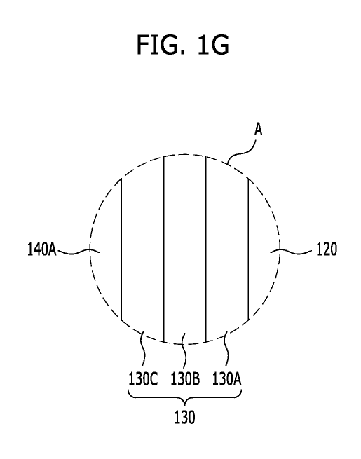

Hereafter, a non-volatile memory device having a three-dimensional structure and a fabrication method thereof in accordance with an embodiment of the present invention are described with reference to FIGS. 1A to 4E.

FIGS. 1A to 1G illustrate a non-volatile memory device having a three-dimensional structure in accordance with an embodiment of the present invention. FIG. 1A is a perspective view of the non-volatile memory device, and FIG. 1B is a plan view of the non-volatile memory device. FIGS. 1C and 1D are cross-sectional views obtained by cutting the non-volatile memory device of FIG. 1A along a line X1-X2 and a line X3-X4, respectively. FIGS. 1E and 1F are cross-sectional views obtained by cutting the non-volatile memory device of FIG. 1A along a line Y1-Y2 and a line Y3-Y4, respectively. FIG. 1G is a cross-sectional view enlarging an A part of the non-volatile memory device shown in FIG. 1A.

Referring to FIGS. 1A to 1G, the non-volatile memory device having a three-dimensional structure includes a substrate 100, a channel structure C extended in a first direction where the channel structure C includes a plurality of inter-layer dielectric layers 110 and a plurality of channel layers 120 that are alternately stacked over the substrate 100, a word line WL extended in a second direction that crosses the first direction and is extended over the channel structure C, a gate electrode 140A protruded from the word line WL in a downward direction to contact a sidewall of the channel structure C, and a memory gate insulation layer 130 interposed between the gate electrode 140A and the channel structure C.

Hereafter, for the sake of convenience in description, the direction that the inter-layer dielectric layers 110 and the channel layers 120 are stacked is defined as a stacking direction or a vertical direction.

The substrate 100 may be, for example, a monocrystalline silicon substrate that may include predetermined structures (not shown) such as a well and an insulation layer.

The channel structure C includes the inter-layer dielectric layers 110 and the channel layers 120 that are alternately stacked. The inter-layer dielectric layers 110 may be oxide layers or nitride layers. The channel layers 120 may be polysilicon layers or monocrystalline silicon layers each doped with a P-type or N-type impurity. The channel structure C may be provided in plural by being extended in the first direction. The multiple channel structures C may be disposed apart from each other with a space between them in parallel to each other in the second direction.

The sidewall of the channel layers 120 contacting the gate electrode 140A (for example, along line X1-X2) may be, for example, protruded toward the gate electrode 140A more than the sidewall of the inter-layer dielectric layers 110. In other words, the sidewall of the channel structure C contacting the gate electrode 140A may have a protrusion and depression shape such that the width of the channel layers 120 may be wider than the width of the inter-layer dielectric layers 110.

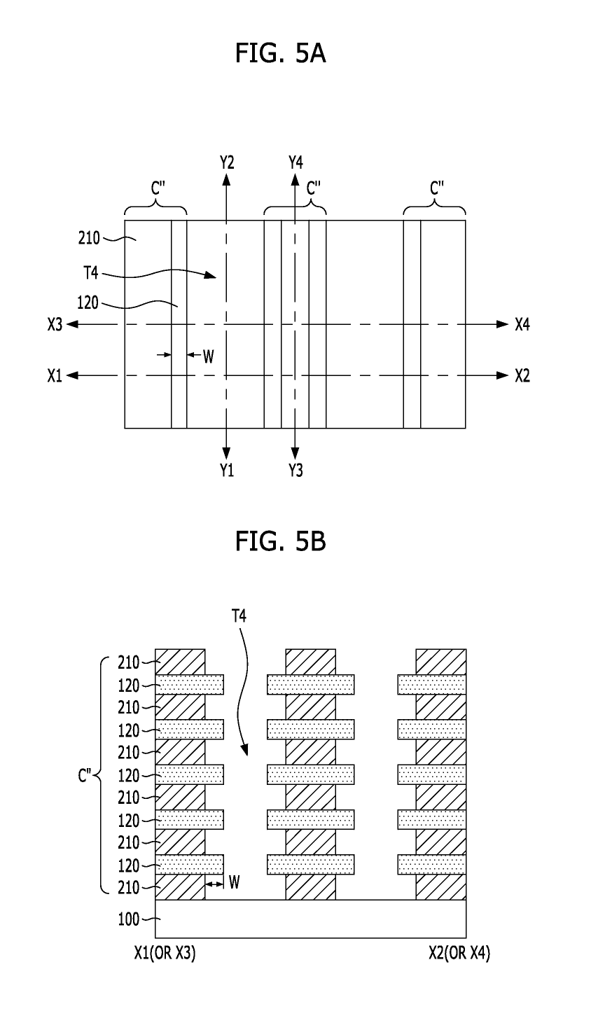

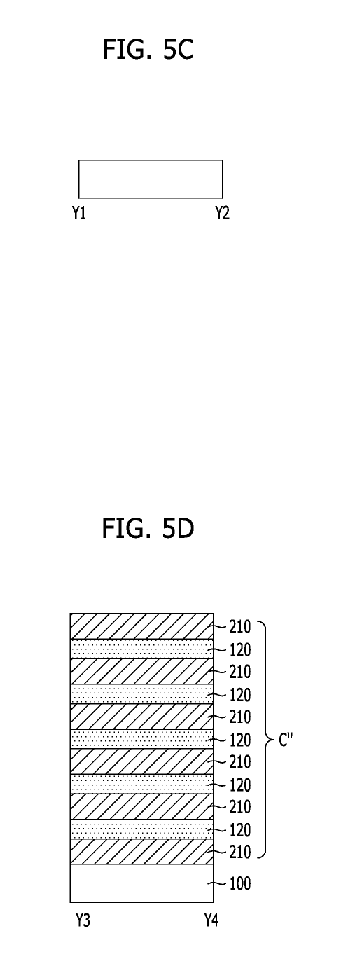

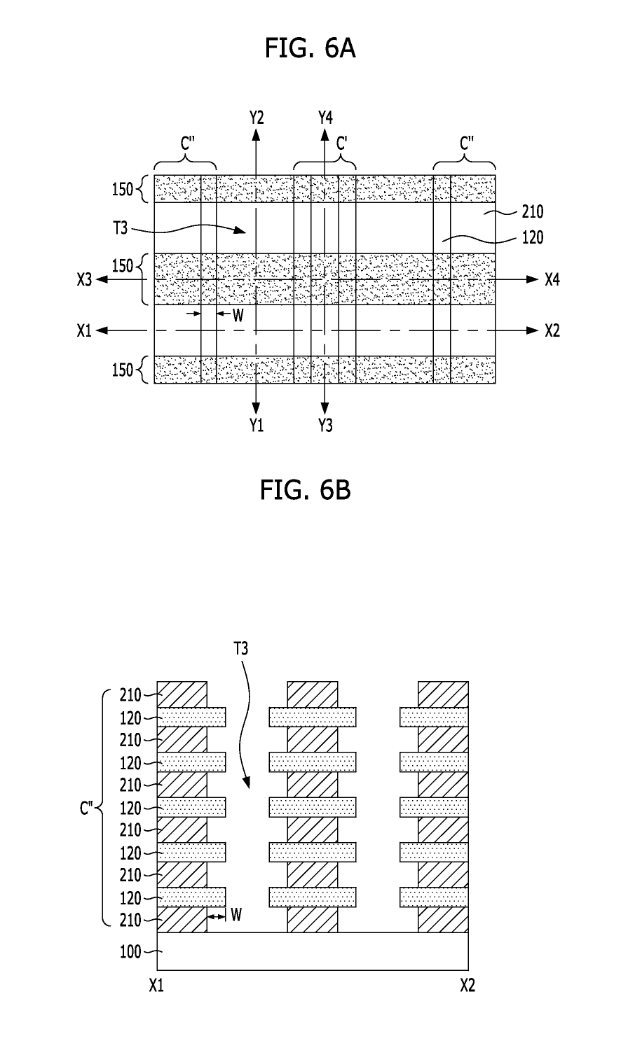

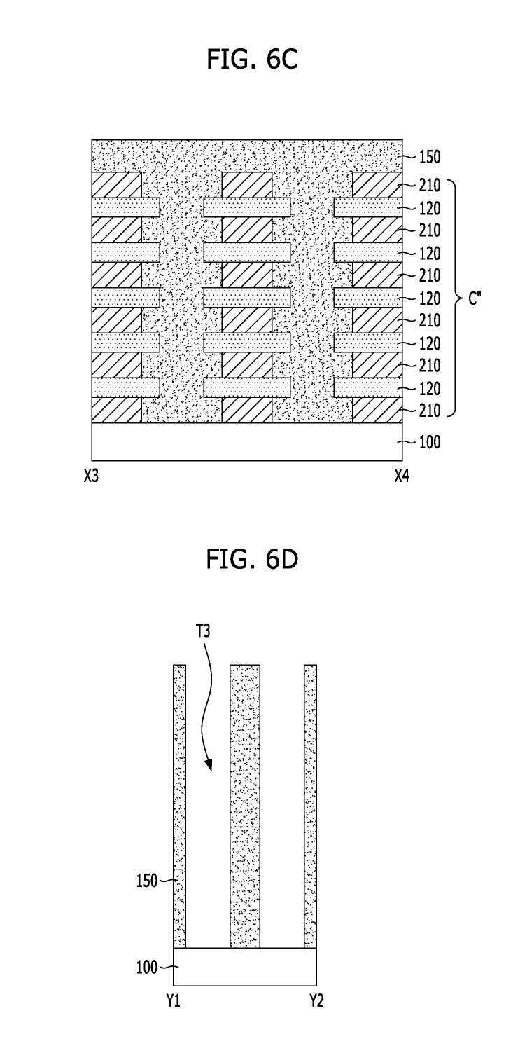

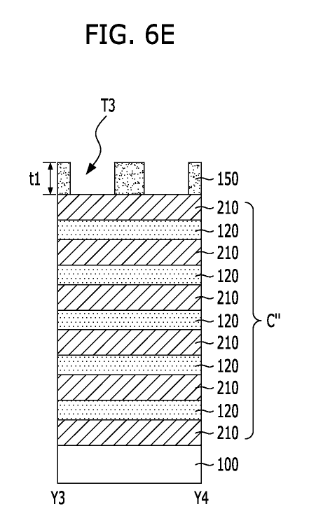

In this embodiment of the present invention, the sidewall of the channel structure C contacting the gate electrode 140A (for example, along line X1-X2) has the protrusion and depression shape as described and the sidewall of the channel structure C that does not contact the gate electrode 140A (for example, along line X3-X4) has a substantially planar shape (see the cross-section of FIGS. 1C and 1D), but the scope of the present invention need not be so limited. According to another embodiment of the present invention, the sidewall of the channel structure C contacting the gate electrode 140A and the sidewall of the channel structure C that does not contact the gate electrode 140A may have substantially the same protrusion and depression. This will be described later on with reference to FIGS. 5A to 6E.

A plurality of word lines WL may be disposed on the channel structure C by being extended in the second direction. The word lines WL may be disposed in parallel to each other while being spaced apart from each other. The word lines WL may comprise, for example, a conductive layer 140B and a silicide layer 140C. The conductive layer 140B may be, for example, a metal layer or a polysilicon layer doped with an impurity. The silicide layer 140C may be optionally disposed over the conductive layer 140B to decrease the resistance of the word lines WL. For example, the silicide layer 140C may be of a metal silicide such as tungsten silicide.

The gate electrode 140A is disposed under the word line WL to fill the space between a channel structure C and another channel structure C. In short, the gate electrode 140A is protruded from the word line WL in a downward direction and disposed between the channel structures C so as to contact the sidewalls of the channel structures C. As a result, one word line WL may electrically connect a plurality of gate electrodes 140A. The sidewall of the channel structure C contacting the gate electrode 140A may mean an indirect contact with the memory gate insulation layer 130 between them.

As described above, among the sidewalls of the channel structures C contacting the gate electrode 140A, the sidewall of the channel layers 120 is protruded toward the gate electrode 140A more than the sidewall of the inter-layer dielectric layers 110, and the sidewall of the gate electrode 140A may be formed along the sidewall profile of the channel structure C. Therefore, since the gate electrode 140A contacts not only the sidewall of the channel layers 120 but also a portion of the upper surface of the channel layers 120 and a portion of the lower surface of the channel layers 120, the contact area between the gate electrode 140A and the channel layers 120 may be increased.

The gate electrode 140A may be a conductive layer such as a metal layer or a polysilicon layer doped with an impurity. In this embodiment of the present invention, the gate electrode 140A may be of substantially the same material as that of the conductive layer 140B of the word line WL, but the scope of the present invention need not be so limited.

The memory gate insulation layer 130 may store data by trapping charges and electrically insulating the gate electrode 140A and the channel structure C from each other. The memory gate insulation layer 130 may be interposed at least between the gate electrode 140A and the channel structure C. The memory gate insulation layer 130 may comprise, for example, a tunnel insulation layer 130A, a charge trapping layer 130B, and a charge blocking layer 130C. The tunnel insulation layer 130A may be disposed close to the channel structure C, and the charge blocking layer 130C may be disposed close to the gate electrode 140A, while the charge trapping layer 130B may be disposed between the tunnel insulation layer 130A and the charge blocking layer 130C (refer to FIG. 1G).

The tunnel insulation layer 130A may be for a charge tunneling between the channel layers 120 and the charge trapping layer 130B. For example, the tunnel insulation layer 130A may be an oxide layer. The charge trapping layer 130B stores data by trapping charges in its deep level trap site. The charge trapping layer 130B may be a nitride layer. Also, the charge blocking layer 130C blocks the charges inside of the charge trapping layer 130B from transferring to the gate electrode 140A. The charge blocking layer 130C may be an oxide layer such as a silicon oxide layer or a metal oxide layer. As a result, the memory gate insulation layer 130 may be an ONO (Oxide-Nitride-Oxide) layer.

The memory gate insulation layer 130 may be interposed not only between the gate electrode 140A and the channel structure C but also between the word line WL and the channel structure C and between the substrate 100 and the gate electrode 140A, as shown in this embodiment of the present invention. However, this is not related to the operation of the non-volatile memory device in accordance with an embodiment of the present invention, and the memory gate insulation layer 130 remains in the process for fabricating the non-volatile memory device.

The inter-gate dielectric layer 150 is an insulation layer for insulating one word line WL and the gate electrode 140A under the one word line WL from an adjacent word line WL and the gate electrode 140A under the adjacent word line WL. The inter-gate dielectric layer 150 may fill the space between the word lines WL and the space between the channel structures C under the space between word lines WL. The inter-gate dielectric layer 150 is not illustrated in the perspective view (FIG. 1A) but shown in the cross-sectional views (FIGS. 1D, 1E, and 1F).

The non-volatile memory device having a three-dimensional structure includes a plurality of memory cells MC (refer to FIG. 1B) that includes the channel layers 120, the memory gate insulation layer 130, and the gate electrode 140A. The memory cells MC may be disposed in the form of a matrix in the first and second directions horizontally, while being stacked in multiple layers in a vertical direction. The number of the stacked memory cells is the same as the number of the stacked channel layers 120. In this embodiment, the memory cells are stacked in five layers, but the scope of the present invention is not be so limited, and the number of the stacked channel layers 120 and the number of the memory cells MC may be changed.

One string ST may be formed by serially coupling the memory cells MC, which are arrayed in a predetermined one layer in the first direction and share the same channel layer 120, between a source selection line (not shown) and a drain selection line (not shown). The string ST may be stacked in multiple layers in the vertical direction. Strings ST stacked in multiple layers while sharing the same channel structure C may be coupled with the same bit line (not shown). Although not illustrated in the drawing, drain selection lines are formed corresponding one-to-one to the channel layers 120 and coupled with the strings ST, respectively.

Also, the multiple memory cells MC arrayed in the second direction in a predetermined layer that share the same word line WL may form one page PAGE. The page PAGE may be stacked in multiple layers in the vertical direction. In short, one word line WL is coupled with the multiple layers of pages PAGE.

In the non-volatile memory device having the above-described structure, a target page PAGE may be selected by enabling a drain selection line coupled with the target page PAGE and disabling the other drain selection lines. Accordingly, a read/write operation may be performed by reading a data stored in a target memory cell MC or storing data in a target memory cell MC on the basis of a page PAGE.

Since the non-volatile memory device having a three-dimensional structure in accordance with an embodiment of the present invention described above includes a plurality of memory cells MC stacked in the vertical direction, the integration degree of the memory cells MC may be increased.

Also, since the gate electrode 140A is formed to surround the portion of the channel layers 120 that protrude compared to the inter-layer dielectric layers 110, the contact area between the gate electrode 140A and the channel layers 120 is increased. Therefore, the memory cells MC may operate more stably.

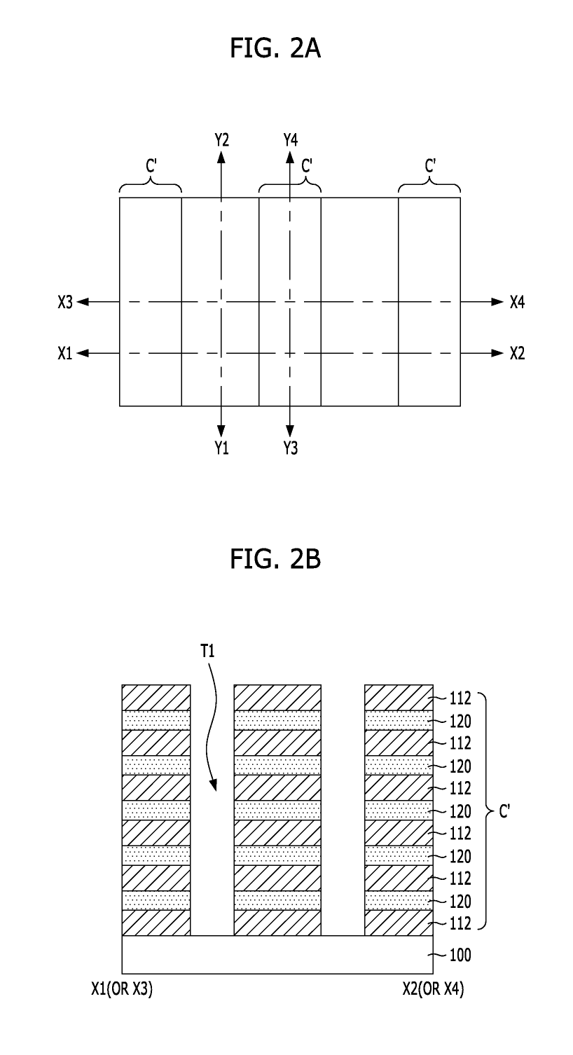

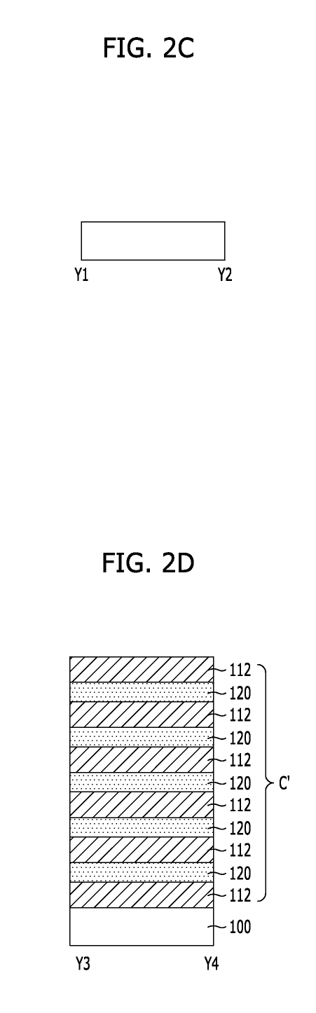

A method for fabricating the non-volatile memory device having a three-dimensional structure in accordance with an embodiment of the present invention is described with reference to FIGS. 1A to 4E. The non-volatile memory device illustrated in FIGS. 1A to 1G may be fabricated through the fabrication process illustrated in FIGS. 2A to 4E. The scope of the present invention, however, need not be so limited. The non-volatile memory device illustrated in FIGS. 1A to 1G may be fabricated through different fabrication processes.

FIGS. 2A to 4E illustrate a method for fabricating a non-volatile memory device having a three-dimensional structure in accordance with an embodiment of the present invention. FIGS. 2A to 4E show the intermediate fabrication process for fabricating the non-volatile memory device of FIGS. 1A to 1G. FIGS. 2A, 3A and 4A are plan views seen from the top of the non-volatile memory device. FIGS. 2B, 3B, 3C, 4B and 4C are cross-sectional views taken along the lines X1-X2, and X3-X4 of the non-volatile memory device shown in FIGS. 2A, 3A and 4A. FIGS. 1D, 2C, 2D, 3D, 3E, 4D, and 4E are cross-sectional views taken along the lines Y1-Y2, and Y3-Y4 of the non-volatile memory device shown in FIGS. 2A, 3A, and 4A. The same reference numbers are given to the same constituent elements as those in FIGS. 1A to 1G. Accordingly, detailed descriptions of these same constituent elements are omitted.

Referring to FIGS. 2A to 2D, a plurality of initial channel structures C′ that are extended in the first direction and include a plurality of initial inter-layer dielectric layers 112 and a plurality of channel layers 120 alternately stacked are formed over the substrate 100. The substrate 100 includes predetermined required structures such as wells and an isolation layer. The initial channel structures C′ may be disposed apart from and parallel to each other in the second direction with a predetermined space between them. The reason that the term “initial” is used is because there may be a modification in the shape during the subsequent processes. The method for forming the initial channel structures C′ is now described in detail.

First, insulation layers for forming the initial inter-layer dielectric layers 112 and material layers for forming the channel layers 120 are deposited alternately over the substrate 100. As described above, the insulation layer for forming the initial inter-layer dielectric layers 112 may be, for example, an oxide layer or a nitride layer, and the material layer for forming the channel layers 120 may be, for example, a monocrystalline silicon layer or a polysilicon layer doped with a P-type impurity or an N-type impurity.

A plurality of the initial channel structures C′ may be formed extending in the first direction by selectively etching the insulation layers and the material layers. Since the initial inter-layer dielectric layers 112 and the channel layers 120 of the initial channel structures C′ are collectively etched, the sidewalls of the initial channel structures C′ may generally be formed to be planes. In other words, the sidewalls of the channel layers 120 and the sidewalls of the initial inter-layer dielectric layers 112 are disposed at the same level without protrusions.

As a result of the above process, a trench T1 exposing the substrate 100 is disposed between the initial channel structures C′.

Subsequently, an ion-implantation process may be performed onto the substrate structure including the initial channel structures C′ in order to control the threshold voltage of the memory cells MC.

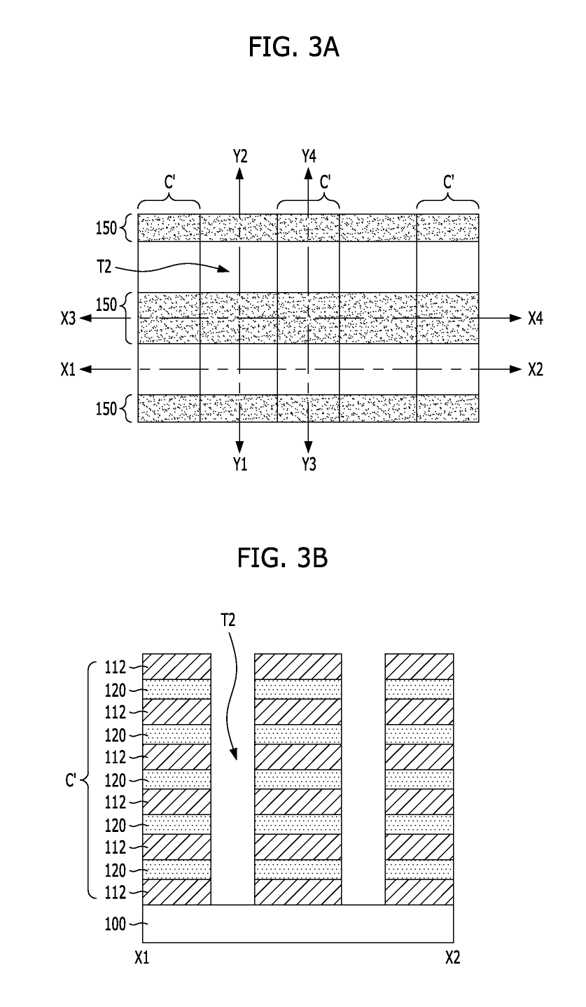

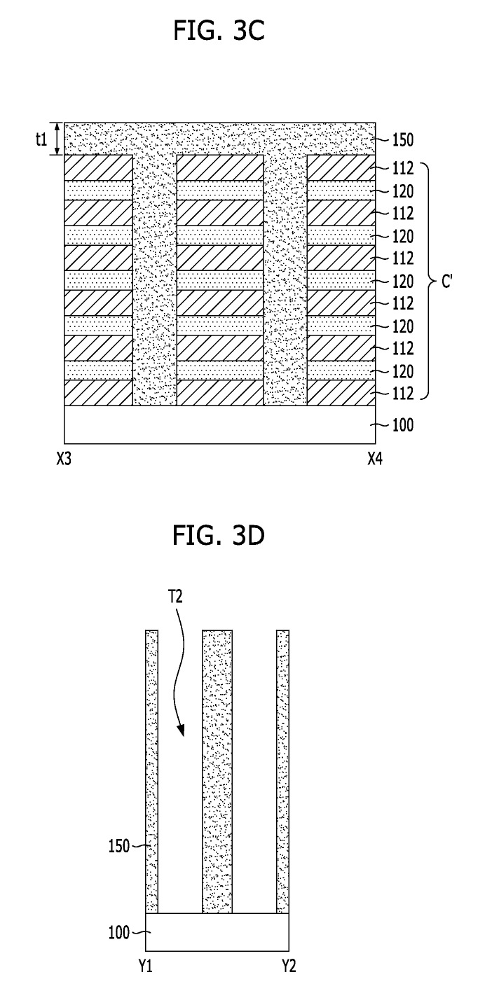

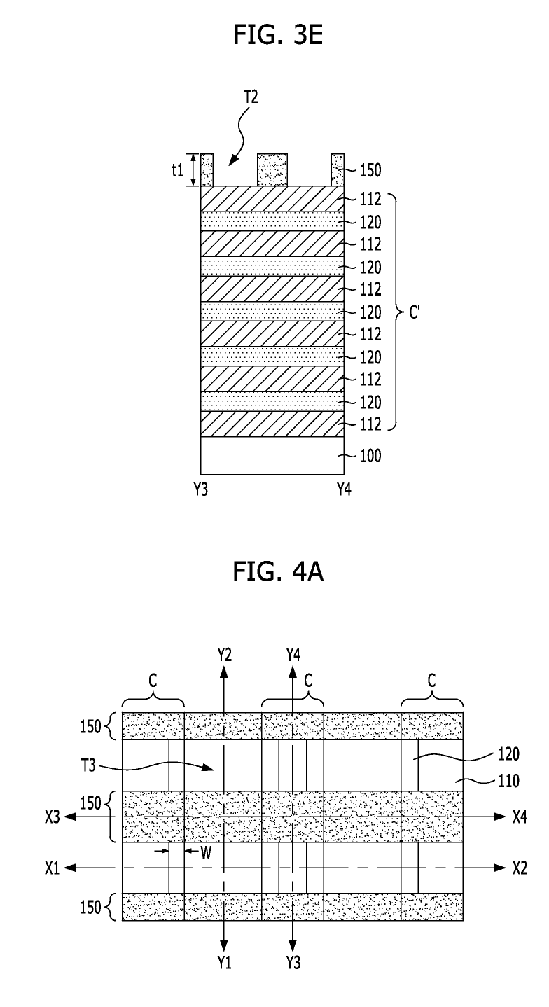

Referring to FIGS. 3A to 3E, the inter-gate dielectric layer 150 is formed over the substrate 100 including the multiple initial channel structures C′ to insulate a gate electrode and the word line WL from each other, which are to be described later. The inter-gate dielectric layer 150 may be formed to fill the space between the word lines WL and the space between the initial channel structures C′ that are disposed under the space between the word lines WL. Accordingly, the inter-gate dielectric layer 150 may have a shape of line extended in the second direction.

To be specific, an insulation layer is formed to have a predetermined thickness t1 over the initial channel structures C′ while sufficiently filling the first trench T1 over the substrate 100 including the initial channel structures C′. Subsequently, a mask pattern (not shown) exposing a region where the word line WL is to be formed is formed over the insulation layer, and the substrate 100 is exposed by using the mask pattern as an etch mask and etching the insulation layer. As a result, the inter-gate dielectric layer 150 is formed. The inter-gate dielectric layer 150 is extended in the second direction and the lower surface of the inter-gate dielectric layer 150 follows the profile of a structure disposed under the inter-gate dielectric layer 150. In other words, the inter-gate dielectric layer 150 may be formed to have the predetermined thickness t1 over the initial channel structures C′ in the portion where the initial channel structures C′ are disposed, and to fill the first trench T1 having the predetermined thickness t1 over the initial channel structures C′ in the portion where the initial channel structures C′ are not disposed, while being extended in the second direction. The inter-gate dielectric layer 150 may be an oxide layer or a nitride layer.

As a result of the above process, an island-type space exposing the substrate 100 is disposed between the initial channel structures C′ and between the inter-gate dielectric layers 150, and a line-type space extended in the second direction is disposed between the inter-gate dielectric layers 150 over the island-type space. The island-type space and the line-type space defined by the initial channel structures C′ and the inter-gate dielectric layer 150 are referred to as second trenches T2, hereafter. The second trenches T2 expose parts of the sidewalls of the initial channel structures C′.

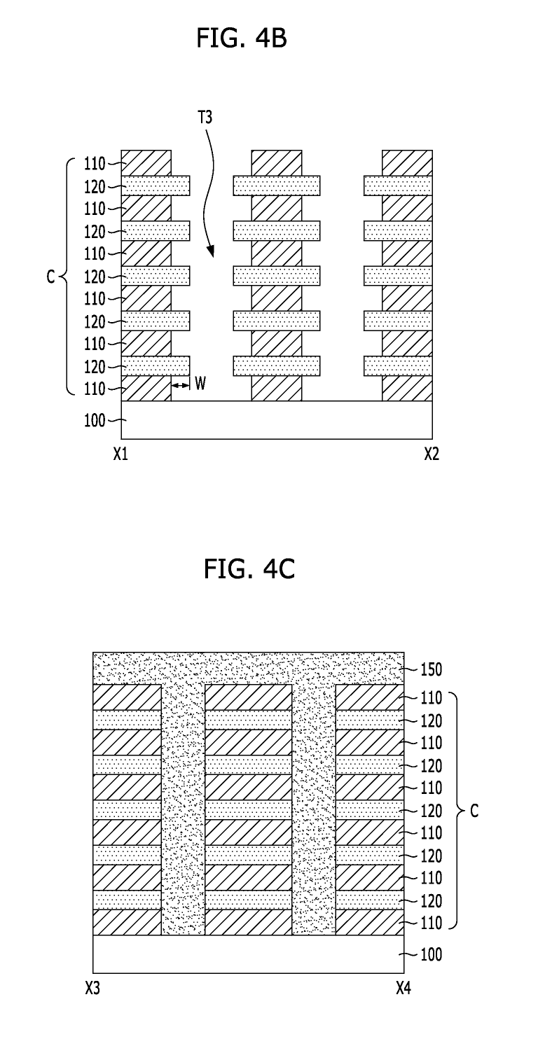

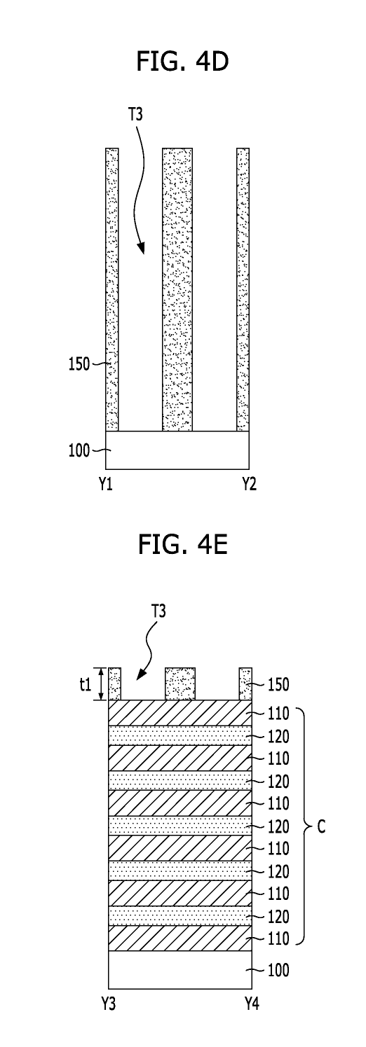

Referring to FIGS. 4A to 4E, the width of the initial inter-layer dielectric layers 112 is decreased in the second direction by removing a predetermined width W of the sidewall of the initial inter-layer dielectric layers 112 in the sidewalls of the initial channel structures C′ exposed by the second trenches T2. Hereafter, the initial inter-layer dielectric layers 112 whose width is decreased is referred to as inter-layer dielectric layers 110. The process of removing the predetermined width W of the sidewall of each initial inter-layer dielectric layer 112 may be performed through an isotropic etch process onto the initial inter-layer dielectric layers 112, e.g., a wet etch process.

As a result of the process, the final channel structures C in which the inter-layer dielectric layers 110 and the channel layers 120 are alternately stacked are formed over the substrate 100. Hereafter, for the sake of convenience in description, the spaces defined by the channel structures C and the inter-gate dielectric layer 150 are referred to as third trenches T3. In other words, the third trenches T3 include the island-type space between the channel structures C and between the inter-gate dielectric layers 150, and the line-type space in the upper portion of the island-type space and between the inter-gate dielectric layers 150. The island-type space of the third trenches T3 is filled with a gate electrode, which is formed through a subsequent process, and the line-type space of the third trenches T3 may be filled with a word line WL through a subsequent process. This will be described later when the corresponding parts are described in detail.

According to the fabrication process, since the second directional width of the inter-layer dielectric layers 110 is narrower than the second directional width of the channel layers 120, the sidewalls of the channel layers 120 among the sidewalls of the channel structure C corresponding to a third trench T3 are protruded toward the island-type space of the third trench T3, compared with the sidewalls of the inter-layer dielectric layers 110. In short, the sidewall of the channel structure C exposed by the third trench T3 may have a protrusion and depression shape which includes a concave portion corresponding to the inter-layer dielectric layers 110 and a convex portion corresponding to the channel layers 120.

Referring back to FIGS. 1A to 1G, the memory gate insulation layer 130 is formed over the substrate structure including the third trenches T3 formed therein, and then the gate electrode 140A filling the island-type space of the third trenches T3 and the word line WL filling the line-type space of the third trenches T3 are formed by forming a conductive layer filling the third trenches T3 over the memory gate insulation layer 130. Herein, the word line WL may have a double layer structure where the conductive layer 140B and the silicide layer 140C are stacked, but the scope of the present invention is not limited to it.

To be specific, the tunnel insulation layer 130A, the charge trapping layer 130B, and the charge blocking layer 130C are sequentially deposited as the memory gate insulation layer 130 over the substrate structure including the third trenches T3 formed therein. For example, an oxide layer, a nitride layer and an oxide layer may be sequentially deposited as the memory gate insulation layer 130.

Subsequently, a conductive layer filling the third trenches T3 is formed over the memory gate insulation layer 130. The conductive layer filling the third trenches T3 may be formed, for example, by depositing a conductive layer over the substrate structure including the memory gate insulation layer 130 and performing a polishing process using the memory gate insulation layer 130 as a polishing stop layer. The conductive layer filling the third trenches T3 is for forming the gate electrode 140A and the word line WL. The conductive layer filling the third trenches T3 may be a metal layer or a polysilicon layer doped with an impurity.

Subsequently, the silicide layer 140C is formed in the uppermost portion of the conductive layer by performing a silicide process. The silicide process may be performed by using a metal material such as titanium (Ti), tantalum (Ta), nickel (Ni) and cobalt (Co) as a source and performing a thermal treatment at a temperature ranging from approximately 100° C. to approximately 1500° C.

According to the process of this embodiment, the gate electrode 140A filling the island-type space of the third trenches T3 and the word line WL filling the line-type space of the third trenches T3 may be formed. The word line WL may have a double layer structure of the conductive layer 140B and the silicide layer 140C when a silicide process is performed.

In the method for fabricating a non-volatile memory device in accordance with an embodiment of the present invention, the channel layers 120 may be formed to be protruded more than the inter-layer dielectric layers 110 just by adding an etch process once, and as a result, the operation characteristics of the fabricated non-volatile memory device may be improved without complicated processes.

Also, since the gate electrode 140A and the word line WL may be formed through a method of filling the third trenches T3, which are defined by the channel structure C and the inter-gate dielectric layer 150, with the conductive layer, it is easy to pattern the gate electrode 140A and the word line WL and to secure reliability, compared with a case using an etch process.

Furthermore, since the gate electrode 140A and the word line WL may be formed simultaneously by simultaneously filling the island-type space and the line-type space of the third trenches T3 with the conductive layer, the fabrication process may be simplified.

Hereafter, a non-volatile memory device having a three-dimensional structure and a fabrication method thereof are described in accordance with another embodiment of the present invention with reference to FIGS. 2A to 2D and FIGS. 5A to 6E.

FIGS. 5A to 6E illustrate a non-volatile memory device having a three-dimensional structure and a method for fabricating the non-volatile memory device in accordance with another embodiment of the present invention. FIGS. 5A and 6A are plan views of the non-volatile memory device shown from the top. FIGS. 5B, 6B and 6C are cross-sectional views taken along the lines X1-X2 and X3-X4 of FIGS. 5A and 6A, and FIGS. 5C, 5D, 6D and 6E are cross-sectional views taken along the lines Y1-Y2 and Y3-Y4 of FIGS. 5A and 6A. In the description of the present embodiment, the difference from the above-described embodiment is described and the description on the other parts is omitted.

Referring back to FIGS. 2A to 2D, a plurality of initial channel structures C′ which are extended in the first direction and include a plurality of initial inter-layer dielectric layers 112 and a plurality of channel layers 120 that are alternately stacked over the substrate 100 are provided

Referring to FIGS. 5A to 5D, the width of the initial inter-layer dielectric layers 112 in the second direction is decreased by removing a portion of the sidewall of the initial inter-layer dielectric layers 112 as much as a predetermined width W among the sidewalls of the initial channel structure C′. Herein, the initial inter-layer dielectric layers 112 with the decreased width are referred to as inter-layer dielectric layers 210.

As a result of the process, the final channel structure C″ where the inter-layer dielectric layers 210 and the channel layers 120 are alternately stacked is formed over the substrate 100. Hereafter, for the sake of convenience in description, the space defined by the channel structure C″ is referred to as a fourth trench T4. The fourth trench T4 is disposed between the channel structures C″ and has a line shape entirely.

After the process, the sidewalls of the channel layers 120 among the sidewalls of the channel structure C″ are protruded toward the fourth trench T4 compared with the sidewalls of the inter-layer dielectric layers 210. In other words, the entire sidewalls of the channel structure C″ may have a protrusion and depression shape including concave portion corresponding to the inter-layer dielectric layers 210 and a convex portion corresponding to the channel layers 120.

Referring to FIGS. 6A to 6E, the inter-gate dielectric layer 150 for insulating a gate electrode and a word line, which are to be described later, is formed over the substrate 100 including the channel structure C″. The inter-gate dielectric layer 150 may be formed to fill the space between word lines and the space between the channel structures C″ under the space between word lines, which is the same as in the above-described embodiment of the present invention.

As a result of the process, island-type space which exposes the substrate 100 is disposed between the channel structures C″ and the inter-gate dielectric layers 150, and line-type space which is extended in the second direction is disposed between the inter-gate dielectric layers 150 over the island-type space. The island-type space and the line-type space may have substantially the same shape as the third trenches T3 described in the above.

The subsequent process to this process, that is, a process of forming the memory gate insulation layer 130 over the substrate structure including the third trenches T3 and then forming the gate electrode 140A and the word line WL filling the third trenches T3 over the memory gate insulation layer 130, is the same as the afore-described embodiment.

To sum up, the method for fabricating a non-volatile memory device in accordance with an embodiment of the present invention is substantially the same as the afore-described embodiment of the present invention, except that the process shown in FIGS. 3A to 3E, which is the process of forming the inter-gate dielectric layer 150, and the process shown in FIGS. 4A to 4E, which is the process of removing a portion of the sidewall of the channel layers 120 to decrease the width, are performed reversely. Accordingly, not only the sidewalls of the channel layers 120 contacting the gate electrode 140A but also the sidewalls of the channel layers 120 not contacting the gate electrode 140A are protruded toward the gate electrode 140A, compared with the inter-layer dielectric layers 210, in the non-volatile memory device in accordance with an embodiment of the present invention.

As described above, the non-volatile memory device fabricated in accordance with an embodiment of the present invention and the fabrication method thereof may have all the effects that may be obtained in an embodiment described before.

The non-volatile memory device and the fabrication method thereof in accordance with an embodiment of the present invention may have increased integration degree as a plurality of memory cells are stacked in a vertical direction, may be fabricated easily, and perform a memory cell operation stably.

While the present invention has been described with respect to the specific embodiments, it will be apparent to those skilled in the art that various changes and modifications may be made without departing from the spirit and scope of the invention as defined in the following claims.

What is claimed is:

1. A non-volatile memory device, comprising:
a channel structure, extended in a first direction, that comprises a plurality of inter-layer dielectric layers and a plurality of channel layers alternately stacked over a substrate such that each inter-layer dielectric layer is adjacent to a corresponding one of the plurality of channel layers;
a word line over the channel structure configured to be extended in a second direction crossing the first direction;
a gate electrode configured to be protruded from the word line in a downward direction and contact a sidewall of the channel structure; and
a memory gate insulation layer configured to be interposed between the gate electrode and the channel structure,
wherein sidewalls of the channel layers contacting the gate electrode are protruded toward the gate electrode, compared with sidewalls of the inter-layer dielectric layers.

2. The non-volatile memory device of claim 1, wherein sidewalls of the channel layers that do not contact the gate electrode are protruded toward the gate electrode in the second direction, compared with the sidewalls of the inter-layer dielectric layers.

3. The non-volatile memory device of claim 1, wherein the memory gate insulation layer comprises a tunnel insulation layer, a charge trapping layer, and a charge blocking layer, and
the tunnel insulation layer is disposed close to the channel structure, the charge blocking layer is disposed close to the gate electrode, and the charge trapping layer is disposed between the tunnel insulation layer and the charge blocking layer.

4. The non-volatile memory device of claim 1, wherein the word line comprises a silicide layer in the uppermost layer of the word line.

5. The non-volatile memory device of claim 1, wherein the word line comprises a structure where a conductive layer and a silicide layer are sequentially stacked, and
the conductive layer of the word line and the gate electrode are formed of the same material.

6. The non-volatile memory device of claim 1, further comprising:
an inter-gate dielectric layer configured to fill a space between the word line and the gate electrode.

7. A method for fabricating a non-volatile memory device, comprising:
forming a channel structure extended in a first direction and comprising a plurality of inter-layer dielectric layers and a plurality of channel layers alternately stacked over a substrate such that each inter-layer dielectric layer is adjacent to a corresponding one of the plurality of channel layers;
forming a memory gate insulation layer over a substrate structure including the channel structure; and
forming a word line over the channel structure extended in a second direction crossing the first direction and a gate electrode protruded from the word line in a downward direction and contacting a sidewall of the channel structure over,
wherein sidewalls of the channel layers contacting the gate electrode are protruded toward the gate electrode, compared with sidewalls of the inter-layer dielectric layers.

8. The method of claim 7, wherein the forming of the channel structure comprises:
forming an initial channel structure comprising a plurality of initial inter-layer dielectric layers and a plurality of channel layers that are alternately stacked over the substrate, is extended in the first direction, and has a planar sidewall; and
removing a width of each sidewall of each initial inter-layer dielectric layer as much as a predetermined width.

9. The method of claim 8, wherein the removing of the predetermined width of each sidewall of each initial inter-layer dielectric layer is performed through an isotropic etch process.

10. The method of claim 8, further comprising:
forming an inter-gate dielectric layer that defines a space where the word line and the gate electrode are to be formed,
wherein the forming of the inter-gate dielectric layer is performed after one of: the forming of the initial channel structure and before the removing of the predetermined width of each sidewall of each initial inter-layer dielectric layer, and after the removing of the predetermined width of each sidewall of each initial inter-layer dielectric layer.

11. The method of claim 7, further comprising:
forming an inter-gate dielectric layer that defines a space where the word line and the gate electrode are to be formed.

12. The method of claim 11, wherein the forming of the word line and the gate electrode comprises:
filling the space defined by the inter-gate dielectric layer with a conductive layer.

13. The method of claim 12, further comprising:
forming a silicide layer in the uppermost layer of the conductive layer by performing a silicide process.

14. The method of claim 7, wherein the forming of the memory gate insulation layer comprises:
sequentially forming a tunnel insulation layer, a charge trapping layer, and a charge blocking layer.
